(19) United States
(12) Patent Application Publication
(10) Pub. No.: US 2026/0202472 A1
(43) Pub. Date: Jul. 16, 2026

(54) SUBSTRATE ASSEMBLY WITH TEST INTERFACE TO CONFIGURE ONBOARD CIRCUITRY

(71) Applicant: Infineon Technologies Austria AG, Villach (AT)

(72) Inventors: Angela KESSLER, Sinzing (DE); Paul YEAMAN, Pelham, NH (US); Paul WESTMARLAND, Surrey (GB); Surendhar SOMASUNDARAM, Santa Clara, CA (US)

(21) Appl. No.: 19/022,255

(22) Filed: Jan. 15, 2025

(51) Int. Cl. G01R 31/319

(52) U.S. Cl. CPC G01R 31/31926; G01R 31/3191; G01R 31/31924

(57) ABSTRACT

A layered assembly as discussed herein can be configured to include a circuit substrate and a test interface. The circuit substrate can be configured to include a first circuit substrate portion and a second circuit substrate portion; the first circuit substrate portion including first circuitry. The test interface can be configured to include at least one electrically conductive path extending between the second circuit substrate portion and the first circuit substrate portion, where the at least one electrically conductive path supports configuration of the first circuitry. Sometime subsequent to configuring the first circuitry, a fabricator resource can be configured to physically partition the first circuit substrate portion and the second circuit substrate portion, resulting in severing of the at least one electrically conductive path.

### BACKGROUND

A conventional power stage assembly can be configured to include multiple switches such as a high side switch and a low side switch that are operated to control delivery of current to a circuit component such as an inductor or other one or more circuit components. In addition to the multiple switches, the conventional power stage assembly can be configured to include driver circuitry to individually control each of the multiple switches.

One type of conventional power stage assembly is implemented as a so-called side by side solution, where respective multiple switches in the power stage are disposed in a single circuit layer and spaced apart from each other. In general, the side-by-side solution provides good thermal performance because it typically is implemented using a large sized circuit board. However, intrinsic to the side-by-side solution is high stray inductance, negatively impacting performance associated with the conventional power stage assembly.

Another type of conventional power stage assembly is implemented as a so-called stack solution of circuit components, where circuit components are stacked upon each other to produce a respective assembly. Such a conventional stack solution may provide a smaller sized circuit board footprint and reduced parasitic effects.

### BRIEF DESCRIPTION

Implementation of clean energy (or green technology) is very important to reduce our impact as humans on the environment. In general, clean energy includes any evolving methods and materials to reduce an overall toxicity to the environment as caused by energy consumption.

This disclosure includes the observation that it is desirable to fabricate switch circuit assemblies to achieve better power efficiency and compactness of same. To this end, the one or more examples as discussed herein may provide one or more benefits such as:
Minimum circuit board footprint for close proximity a respective power converter assembly to a processor
Lowest parasitic inductance and capacitance and resistance supporting highly efficient conversion of an input voltage into an output voltage
Good thermal performance for dissipating heat quickly and providing high power with respect to the size of the power converter assembly

In certain instances, it is desirable to include appropriate test pads to trim circuitry (such as to match a driver circuit with a respective field effect transistor) in accordance with each customer's requirements. This disclosure further includes the observation that implementation of a stacked circuit component assembly renders it difficult to implement test pads for testing and trimming respective circuitry in an assembly.

A conventional solution to providing test pads is to use the conventional technology to route all required pads to the package top side and perform testing applied to the top of the assembly. Unfortunately, this conventional technique requires additional space for pads on the top of a respective circuit board package. In other words, this requires a larger circuit board package. As previously discussed, it is desirable to provide a smallest possible package supporting delivery of a large amount of power to a respective load.

Techniques as discussed herein provide novel ways of testing and trimming (configuring) one or more instances of circuitry disposed in a respective electronic assembly.

More specifically, an assembly as discussed herein can be configured to include a circuit substrate and a test interface. The circuit substrate can be configured to include a first circuit substrate portion and a second circuit substrate portion; the first circuit substrate portion including first driver circuitry. The test interface of the assembly can be configured to include at least one electrically conductive path extending between the second circuit substrate portion and the first circuit substrate portion, where the at least one electrically conductive path operative to support configuring of the first driver circuitry.

In one example, configuring of the one or more components such as driver circuitry in the first circuit substrate portion may include trimming the driver circuitry to match corresponding one or more switches driven by the driver circuitry. The one or more switches may also reside in the first substrate portion.

Note further that the assembly as discussed herein can be configured to include any type of circuitry. In one example, as previously discussed, the first circuit substrate portion includes first switch circuitry controlled by the first driver circuitry. As further discussed herein, the first switch circuitry may include multiple switches such as a first switch (such as a high side switch implemented as a first field effect transistor) and a second switch (such as a low side switch implemented as a second field effect transistor) controlled by the first driver circuitry. The first driver circuitry may include a first driver operative to drive the first field effect transistor; the first driver circuitry may include a second driver operative to drive the second field effect transistor.

Note further that the first circuit substrate portion may further include one or more surface mount pads such as a first electrically conductive element disposed on a first surface of or in the first circuit substrate portion. The first electrically conductive element may be connected to both a source node of the first switch and a drain node of the second switch.

In a further example, the second circuit substrate portion can be configured to include second driver circuitry operative to control second switch circuitry disposed in the second circuit substrate portion, where the second switch circuitry includes third switch and a fourth switch controlled by the second driver circuitry.

Still further, the first circuit substrate portion may be disposed adjacent to and contiguous with respect to the second circuit substrate portion in the circuit substrate. The circuit substrate can be configured to include any number of circuit substrate portions disposed in a sequence.

Yet further, the test interface spanning the second circuit substrate portion and the first circuit substrate portion of the assembly can be configured to include a group of conductive elements disposed on a first surface of the circuit substrate, where the electrically conductive elements may include a first conductive element and a second conductive element. The at least one electrically conductive path at as discussed herein can be configured to include a first electrically conductive path and a second electrically conductive path. In one example, the first electrically conductive path is configured to extend between the first conductive element and a first node of the first driver circuitry; the second electrically conductive path is configured to extend between the second conductive element and a second node of the first driver circuitry.

Note that at least a portion of the first electrically conductive path may be disposed internal to the circuit substrate between the first surface of the circuit substrate and a second surface of the circuit substrate; at least a portion of the second electrically conductive path may be disposed internal to the circuit substrate between the first surface of the circuit substrate and a second surface of the circuit substrate.

In further examples as discussed herein, the test interface can be configured to include a sequence of electrically conductive elements disposed on a first surface of the circuit substrate, where the sequence of conductive elements includes a first conductive element and a second conductive element. The sequence of conductive elements may be disposed along a boundary between the first circuit substrate portion and the second circuit substrate portion.

In yet further examples as discussed herein, the at least one electrically conductive path includes multiple electrically conductive paths; the circuit substrate can be configured to include a defined boundary (such as extraneous/sacrificial substrate material disposed) between the first circuit substrate portion and the second circuit substrate portion. The multiple electrically conductive paths can be configured to pass through the defined boundary.

Note further that a fabricator can be configured to subsequently implement a cut along the defined boundary to sever the multiple electrically conductive paths from extending between the first circuit substrate portion and the second circuit substrate portion. Implementation of the current for separation may include removal of the extraneous substrate material.

The first circuit substrate portion can be included in a first power converter assembly or module; the second circuit substrate portion can be included in a second power converter assembly or module.

As further discussed herein, one or more circuit components can be affixed to each of the first circuit substrate portion and the second circuit substrate portion. The test interface (such as extending/spanning between the second circuit substrate portion and the first circuit substrate portion) can be configured to include electrically conductive elements (such as surface pads or other suitable entity fabricator from metal) disposed on a surface of the circuit substrate along the defined boundary.

In one example, prior to separating the first circuit substrate portion from the second circuit substrate portion via the fabricator, the test interface enables trimming of circuitry disposed in the first circuit substrate portion via application of the input signals supplied to test pads of the test interface disposed on the second circuit substrate portion as well as monitoring of signals received from the test pads of the test interface disposed on the second circuit substrate portion. The calibration or trimming of the test hardware may further include, subsequent to performing testing of the first driver circuitry driving the respective one or more switches, producing configuration settings (such as digital information or other types of information) that are stored in the first driver circuitry for subsequent operation of the first driver circuitry controlling the respective one or more switches embedded in the first circuit substrate portion.

As previously discussed, the at least one electrically conductive path of the test interface can be configured to include first electrically conductive paths extending between the second circuit substrate portion and the first circuit substrate portion. The circuit substrate can be configured to further include a third circuit substrate portion disposed adjacent to the second circuit substrate portion. The second circuit substrate portion may include second driver circuitry. The test interface (such as including a second test interface) as discussed herein may further include second electrically conductive paths extending between the third circuit substrate portion and the second circuit substrate portion, where the second electrically conductive paths are operative to support trimming of the second driver circuitry.

Accordingly, a sequence of circuit substrate portions disposed in an overall substrate assembly and corresponding test interfaces between each pair of circuit substrate portions enables beneficial testing and calibrating different circuitry disposed in the substrate assembly.

In accordance with further examples as discussed herein, the first driver circuitry may be embedded in the first circuit substrate portion between a first surface (such as top) of the circuit substrate and a second surface (such as bottom) of the circuit substrate. The first circuit substrate portion can be configured to include switch circuitry (such as one or more switches) controlled by the first driver circuitry. In one example, the switch circuitry includes a first switch electrically coupled to a second switch.

Yet further, as previously discussed, any of the assemblies as discussed herein can be configured to include first test pads disposed on a first surface of the first circuit substrate portion as well as second test pads disposed on a second surface of the second substrate portion. It is noted that the first test pads and the second test pads may be used to support calibration of the first driver circuitry in a manner as previously discussed. The first test pads may be electrically connected to a first circuit in the first circuit substrate portion, the first circuit given by the first driver circuitry; and wherein the second test pads are electrically connected to the first driver circuitry and the at least one electrically conductive path.

Further examples as discussed herein a method comprising: receiving a circuit substrate including a first circuit substrate portion and a second circuit substrate portion, the first circuit substrate portion including first driver circuitry; physically coupling test hardware to a test interface disposed on the circuit substrate, the test interface including at least one electrically conductive path extending between the second circuit substrate portion and the first circuit substrate portion; via the test hardware, using the at least one electrically conductive path to configure operation of the first driver circuitry; and subsequent to testing via application of the test hardware to the test interface, partitioning the second circuit substrate portion to be electrically isolated from the first circuit substrate portion.

In one example, partitioning of the second circuit substrate portion to be electrically isolated from the first circuit substrate portion includes a fabricator physically severing the at least one electrically conductive path extending between the second circuit substrate portion in the first circuit substrate portion.

As previously discussed, the first circuit substrate portion can be disposed adjacent to and contiguous with respect to the second circuit substrate portion prior to the physical severing or partitioning of the first circuit substrate portion and the second circuit substrate portion. Further, as previously discussed, the test interface can be configured to include: a group of conductive elements disposed on a first surface of the circuit substrate, the conductive elements including a first conductive element and a second conductive element; the at least one electrically conductive path associated with the test interface can be configured to include a first electrically conductive path and a second electrically path; the first electrically conductive path can be configured to extend between the first conductive element and a first node of the first driver circuitry; the second electrically conductive path can be configured to extend between the second conductive element and a second node of the first driver circuitry.

Coupling (or physically contacting pins) of the test hardware to the test interface: may include i) contacting a first test pin of the test hardware to the first conductive element, and ii) contacting a second test pin of the test hardware to the second conductive element, and so on.

Using the at least one electrically conductive path to configure operation of the first driver circuitry (trimming the first driver circuitry to drive respective one or more switches) may include the test hardware: i) receiving a first signal communicated from the first node of the first driver circuitry over a combination of the first electrically conductive path and the first conductive element of the test interface, and ii) transmitting a second signal through the second test pin of the test hardware over the second electrically conductive path of the test interface to the second node of the first driver circuitry.

As discussed herein, techniques herein are well suited for use in the field of implementing/fabricating power converter assemblies at any stage of a fabrication process to support testing and/or calibration (such as trimming or other suitable process). However, it should be noted that examples herein are not limited to use in such applications and that the techniques discussed herein are well suited for other applications as well.

Additionally, note that although each of the different features, techniques, configurations, etc., herein may be discussed in different places of this disclosure, it is intended, where suitable, that each of the concepts can optionally be executed independently of each other or in combination with each other. Accordingly, the one or more present inventions as described herein can be implemented and viewed in many different ways.

Also, note that this preliminary discussion of examples herein (BRIEF DESCRIPTION OF EXAMPLES) purposefully does not specify every example and/or incrementally novel aspect of the present disclosure or claimed invention(s). Instead, this brief description only presents general examples and corresponding points of novelty over conventional techniques. For additional details and/or possible perspectives (permutations) of the invention(s), the reader is directed to the Detailed Description section (which is a summary of examples) and corresponding figures of the present disclosure as further discussed below.

### BRIEF DESCRIPTION OF THE DRAWINGS

FIG. 1 is an example side view diagram illustrating fabrication of one or more sequences of multiple circuit substrate portions in a respective circuit substrate as discussed herein.

FIGS. 2A, 2B, 2C, 2D are is an example diagram illustrating implementation of circuitry in each respective circuit substrate portion in a circuit substrate as discussed herein.

FIG. 3 is an example 3-D diagram illustrating a sequence of multiple circuit substrate portions (such as including at least a first layer and a second layer) in a circuit substrate as discussed herein.

FIG. 4 is an example 3-D diagram illustrating a sequence of multiple circuit substrate portions (such as including at least a first layer, a second layer, and a third layer) in a circuit substrate as discussed herein.

FIG. 5 is an example 3-D diagram illustrating a sequence of multiple circuit substrate portions (such as including at least a first layer, a second layer, a third layer, and a fourth layer) in a circuit substrate as discussed herein.

FIG. 6 is an example diagram illustrating application of test hardware in contact with a respective circuit substrate portion to trim or apply configuration settings to circuitry disposed in the respective circuit substrate portion as discussed herein.

FIG. 7 is an example diagram illustrating dicing and separation of the different instances of circuit substrate portions disposed in the circuit substrate as discussed herein.

FIG. 8 is an example 3-D diagram illustrating fabrication of a power converter assembly using a pre-calibrated circuit substrate portion as a base substrate as discussed herein.

FIG. 9 is an example side view diagram illustrating how implementation of a respective test interface and corresponding test pads do not interfere with implementation of power converter circuitry associated with a respective circuit substrate portion and final assembly of a circuit board and multiple instances of power converter assemblies disposed on a respective host substrate as discussed herein.

FIG. 10 is an example diagram illustrating fabrication of a respective circuit substrate to support configuration as discussed herein.

The foregoing and other objects, features, and advantages of the invention will be apparent from the following more particular description of preferred examples herein, as illustrated in the accompanying drawings in which like reference characters refer to the same parts throughout the different views. The drawings are not necessarily to scale, with emphasis instead being placed upon illustrating the examples, principles, concepts, etc.

### DETAILED DESCRIPTION

A conventional power converter may include a half bridge circuit and corresponding high side switch circuitry and low side switch circuitry to convert an input voltage into an output voltage. Further, the conventional power converter may include a driver circuitry to control operation of both the half bridge and the switch circuitry.

In general, one or more instances of a respective power converter assembly as discussed herein can be used to supply power to any load such as a computing system. In the case of a computing system, the closer the power supply (including the one or more power converters) is mounted to the computing system or load in general, the lower the magnitude of corresponding parasitic inductance, capacitance, etc., associated with the power converter system, reducing overall power losses associated with delivery of power from the power converter system to the computing system. In contrast to conventional techniques, novel techniques as discussed herein include fabricating the power converter assemblies associated with the power converter system to produce high output power in a small package.

To support increased power density such as a magnitude of power supplied to a load with respect to a volume of a power converter, the novel techniques as discussed herein include configuring (such as trimming, calibrating, etc.), circuitry in each of the circuit substrate portions used in fabrication of a respective power converter assemblies. In one example, each of the one or more circuit substrate portions associated with a circuit substrate can be configured prior to dicing each of the circuit substrate portions into submodules. Accordingly, techniques herein include supporting a mass configuring of circuit substrate portions associated with a circuit substrate and the dicing the circuit substrate into circuit substrate portions.

In one example, each of the circuit substrate portions includes driver circuitry that is trimmed before final population of the respective circuit substrate with additional components such as inductors, capacitance, etc., mounted on the respective circuit substrate.

Accordingly, this disclosure includes the observation that conventional techniques of implementing one or more test pads in a finally assembled power converter circuitry is that they require a large footprint substrate to accommodate the extra one or more test pads, even though the test pads are no longer used during operation of the respective power converter assembly after configuration.

One solution is to is to use so-called CE (a.k.a., Chip Embedding) technology to route all required pads associated with a respective power converter package to the top side of the respective power converter package and then implement testing via application of a test circuit to the top side of the respective power converter package to calibrate circuitry within that power converter package.

As discussed herein, a novel solution includes configuring a respective circuit substrate portion and routing of test pads from a first package to the adjacent package, where the test pads are located in an uncritical area in regards of electrical and thermal path. This enables the creation of a better so-called Rth compared to a solution where these “thermal areas” are otherwise occupied by the test pads. As further discussed herein, after so-called singulation (such as dicing and separating), the circuit substrate portions will be isolated and have no function with respect to each other anymore. In one example, the last row of pads in a respective circuit substrate portion is routed into the frame of the PCB so that a respective fabricator is able to control the amount of packages per panel (such as circuit substrate) and save on assembly costs.

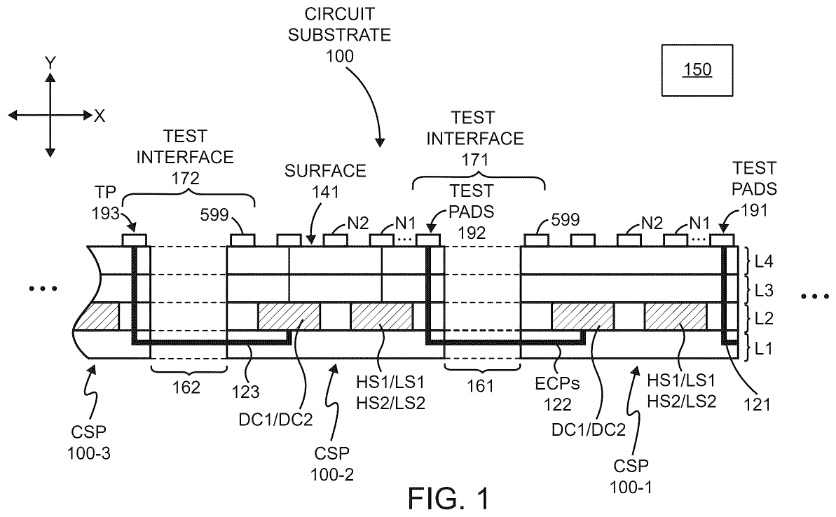

Now, more specifically, FIG. 1 is an example side view diagram illustrating fabrication of multiple circuit substrate portions in a respective circuit substrate as discussed herein.

In this example, the circuit substrate 100 (a.k.a., assembly) includes multiple layers such as layer #L1, layer #L2, layer #L3, layer #L4, and so on. Each of the layers in the circuit substrate 100 may include circuit components, circuit pads, semiconductor chip components, driver circuitry, switch circuitry, amplifier circuitry, connective paths, etc.

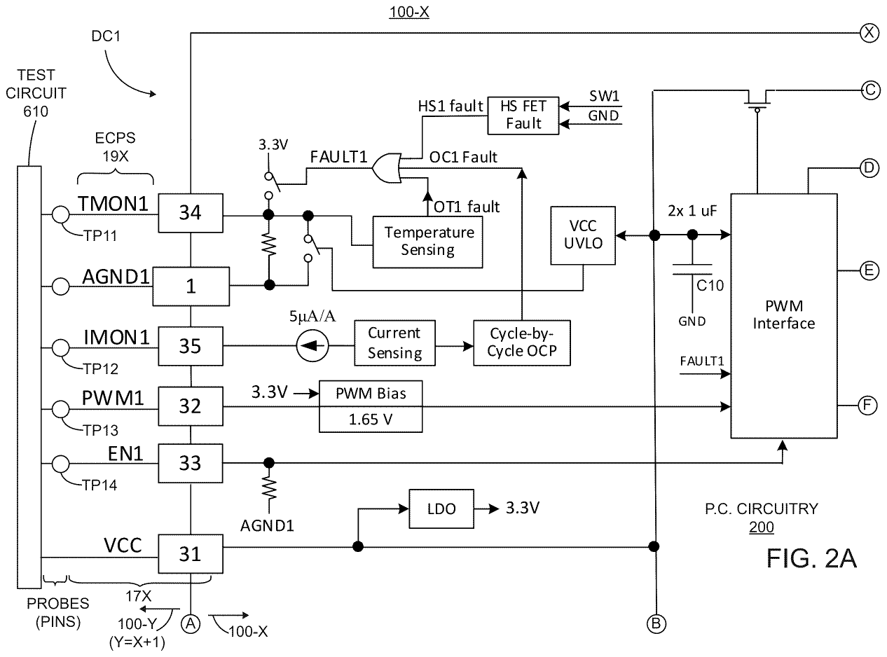

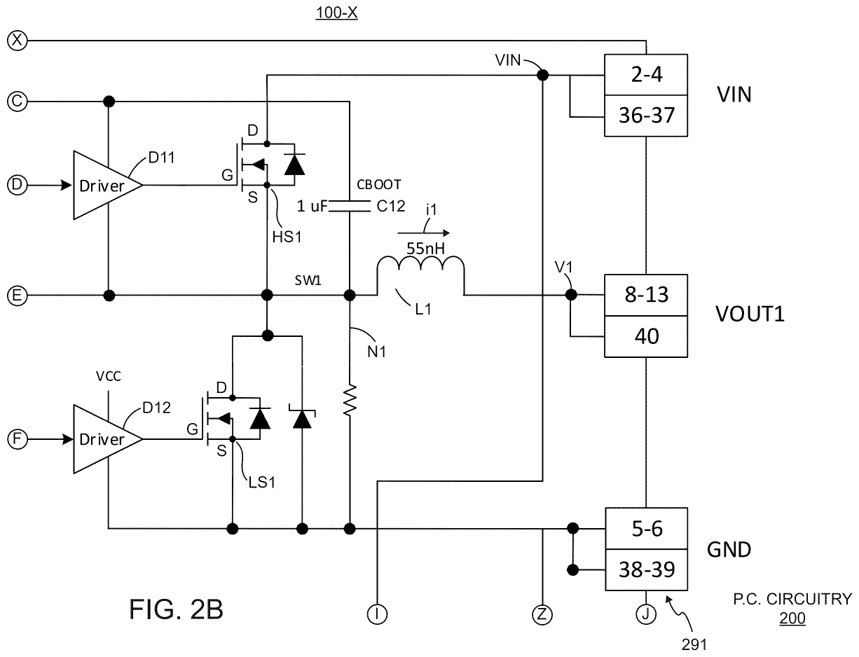

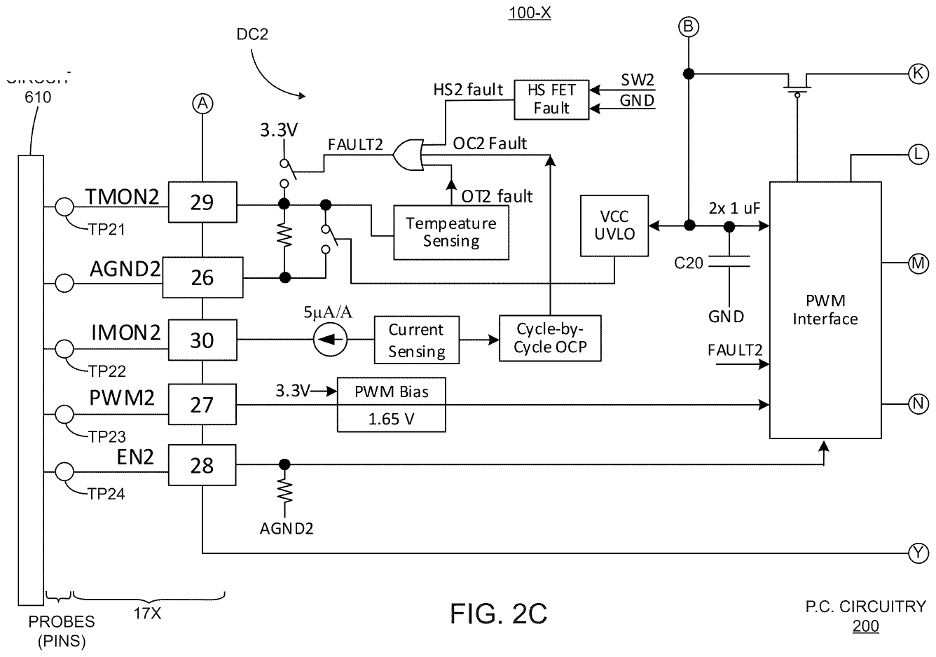

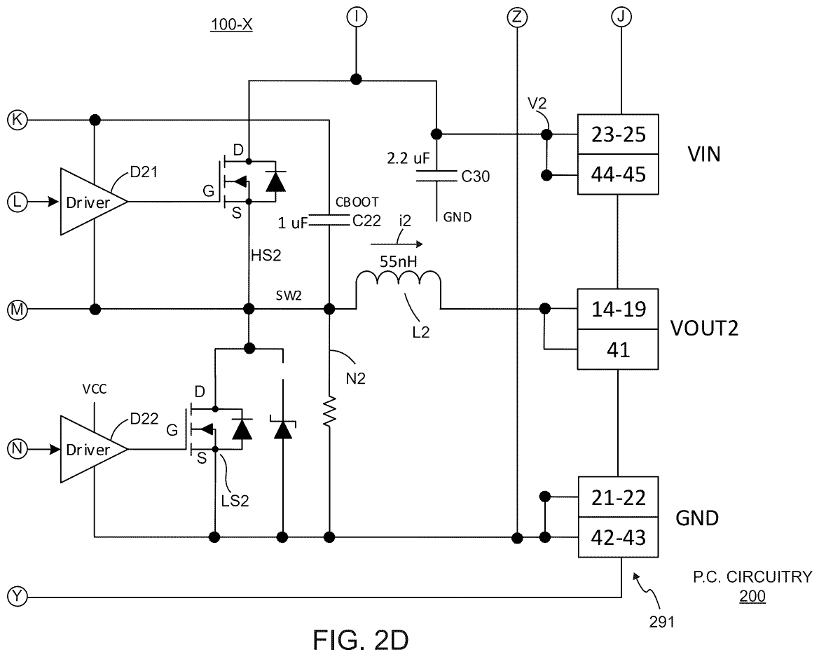

An example of the circuitry supported by each different circuit substrate portion of the circuit substrate 100 is shown in FIGS. 2A, 2B, 2C, and 2D. Certain components in the circuitry (such as power converter circuitry supporting conversion of an input voltage into an output voltage) shown in FIGS. 2A, 2B, 2C, and 2D, may be affixed directly or indirectly to a respective one or more surface (such as including surface 141 or top surface) of the corresponding circuit substrate portion.

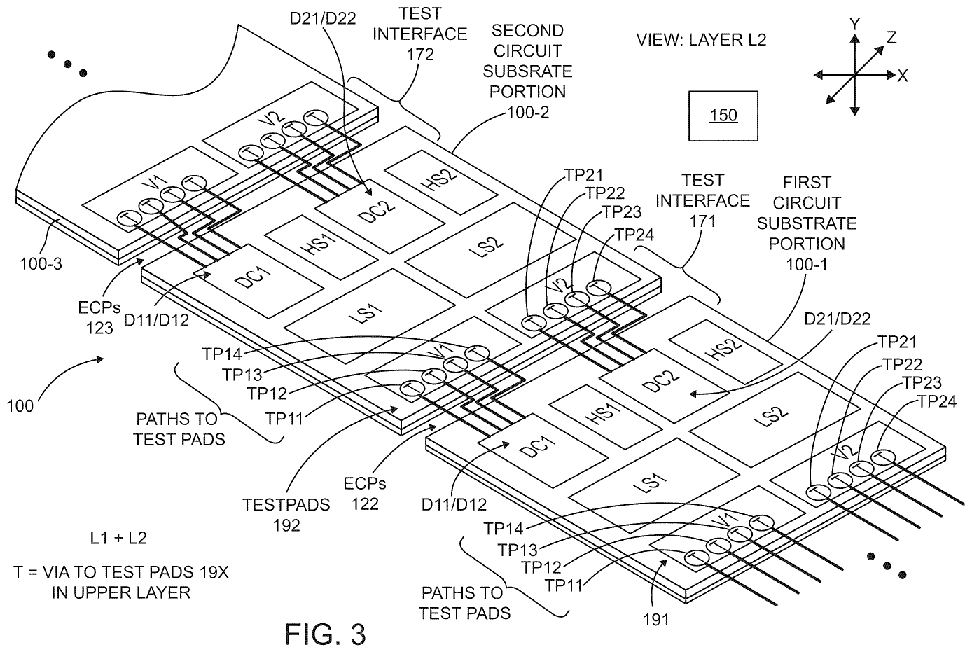

In one example, a first instance of the circuitry DC1/DC2 (including driver circuitry D11 and D12 as will be later discussed in FIG. 3) and a first instance of the high side and low side switch circuitry HS1/LS1 and HS2/LS2 are disposed in the layer #L2 (or one or more other layers of the circuit substrate portion 100-1) of the circuit substrate portion 100-1; a second instance of the circuitry DC1/DC2 (including driver circuitry D11/D12 and driver circuitry D21/D22) and a second instance of the high side and low side switch circuitry HS1/LS1 and HS2/LS2 are disposed in the layer #L2 (or one or more other layers of the circuit substrate portion 100-2) of the circuit substrate portion 100-2; and so on.

Referring again to FIG. 1, note that the circuit substrate 100 in this example includes any number of adjacent circuit substrate portions.

For example, the circuit substrate 100 includes circuit substrate portion 100-1 delineated or spaced apart from the second circuit portion 100-2 via the extraneous substrate material 161 (such as layers of material); the circuit substrate includes circuit structure a portion 100-2 from the third circuit substrate portion 100-3 via the extraneous substrate material 162 (such as layers of material); and so on. Each instance of the extraneous substrate material supports multiple electrically conductive paths (122, 123, etc.) between a particular one of the circuit substrate portion and an adjacent circuit substrate portion.

The electrically conductive paths 122, 122, etc., may be disposed in a respective one or more layers of the circuit substrate 100 or in between one or more layers of the respective circuit substrate 100.

As further shown, the circuit substrate 100 includes a respective test interface between each pair of adjacent circuit substrate portions. For example, the circuit substrate 100 further includes a respective test interface 171 disposed between the circuit substrate portion 100-1 and the circuit substrate portion 100-2; the circuit substrate 100 further includes a test interface 172 does those between the circuit substrate portion 100-2 and the circuit substrate portion 100-3; and so on.

As further shown, the first circuit substrate portion 100-1 is disposed adjacent to and contiguous with respect to the second circuit substrate portion 100-2 in the circuit substrate 100.

Note again that the circuit substrate 100 can be configured to include any number of circuit substrate portions disposed in any of one or more dimensions. In one example, the circuit substrate 100 includes a two-dimensional array of circuit substrate portions.

It is further noted that each of the test interfaces 171, 172, etc., includes multiple test pads as well as corresponding electrically conductive paths extending from a surface 141 of the circuit substrate 100 and corresponding circuitry (such as any circuitry associated with or disposed in the power converter circuit 200) embedded in the circuit substrate 100.

More specifically, the test interface 171 includes test pads 192 (later referred to as TP11, TP12, TP13, TP14, TP21, TP22, TP23, TP24, etc.) and corresponding multiple electrically conductive paths 122. Each of the multiple electrically conductive paths 122 of the test interface 171 extends between a respective test pad of the multiple test pads 192 and the instances of driver circuitry D11/D12 (or any circuitry in the power converter circuit 200) embedded in any of the layers of the circuit substrate portion 100-1; each of the multiple electrically conductive paths 123 of the test interface 172 extends between a respective test pad of the multiple test pads 193 and the instances of driver circuitry D11/D12 in the circuit substrate portion 100-2; and so on.

As shown, first portions of the electrically conductive paths 122 can be configured to extend orthogonally from the surface 141 through one or more layers of the second circuit substrate portion 100-2; second portions of the electrically conductive paths 122 extend parallel through or between one or more layers (such as any of layers #L1, #L2, #L3, etc.) of the circuit substrate 100 between the second circuit substrate portion 100-2 and the first circuit substrate portion 100-1 to the driver circuitry D11/D12 or other circuitry in the first circuit substrate portion 100-1.

In a similar manner, the electrically conductive paths 123 extend orthogonally from the surface 141 and corresponding test pads 193 from the electrically conductive paths 123 through one or more layers of the third circuit substrate portion 100-3; the electrically conductive paths 123 extend parallel through one or more layers (such as any of layers #L1, #L2, #L3, etc.) of the circuit substrate 100 between the third circuit substrate portion 100-3 and the second circuit substrate portion 100-2 to the instances of the driver circuitry D11/D12 or other circuitry in the second circuit substrate portion 100-2.

In one example, as further discussed herein, the test interface 171 including test pads 192 and corresponding electrically paths 122 support trimming (calibrating, configuring, etc.) of driver circuitry D11/D12 associated with the circuit substrate portion 100-1 with respect to corresponding switch circuitry therein. Note that trimming may include configuring the respective driver D11 with appropriate one or more digital configuration settings or analog settings such that driver D11 produces a respective control signal to control the state of the high side switch circuitry HS1 in the desired manner; trimming may further include configuring the respective driver D12 with appropriate one or more digital configuration settings or analog settings such that driver D12 produces a respective control signal to control the state of the low side switch circuitry LS1 in a desired manner; and so on.

The test interface 172 including test pads 193 and corresponding electrically paths 123 support trimming of driver circuitry D11/D12 associated with the circuit substrate portion 100-2, and so on.

In one example, as previously discussed, the driver circuitry DC1 in the circuit substrate portion 100-1 includes driver circuitry D11 and driver circuitry D12. The first circuit substrate portion 100-1 includes first switch circuitry such as switch circuitry HS1 controlled by the driver circuitry D11 and switch circuitry LS1 controlled by the driver circuitry D12. Trimming of the driver circuitry D11/D12 in each of the corresponding circuit substrate portions provides more efficient control of switching on and off of the respective switch circuitry in the corresponding circuit substrate portion.

In one example, the circuit substrate portion 100-1 further includes a first conductive element N1 (such as a first surface mount pad) disposed on a surface 141 of the first circuit substrate portion 100-1, where the first conductive element N1 is electrically connected to both a source node S of the first switch HS1 and a drain node D of the second switch LS1.

The circuit substrate portion 100-1 may include a second conductive element N2 (such as a second surface mount pad) disposed on a surface 141 of the first circuit substrate portion 100-1, where the first conductive element is electrically connected to both a source node S of the third switch HS2 and a drain node D of the fourth switch LS2.

The combination of FIGS. 2A, 2B, 2C, and 2D is an example diagram illustrating implementation of circuitry in each respective circuit substrate portion in a circuit substrate as discussed herein.

This example power circuit 200 in FIGS. 2A, 2B, 2C, and 2D illustrates the circuit components associated with the driver circuitry DC1 and driver circuitry DC2 as well as other circuit components disposed in each instance of the circuit substrate portion 100-X (where X is any integer value 1, 2, 3, etc.) of the respective circuit substrate 100.

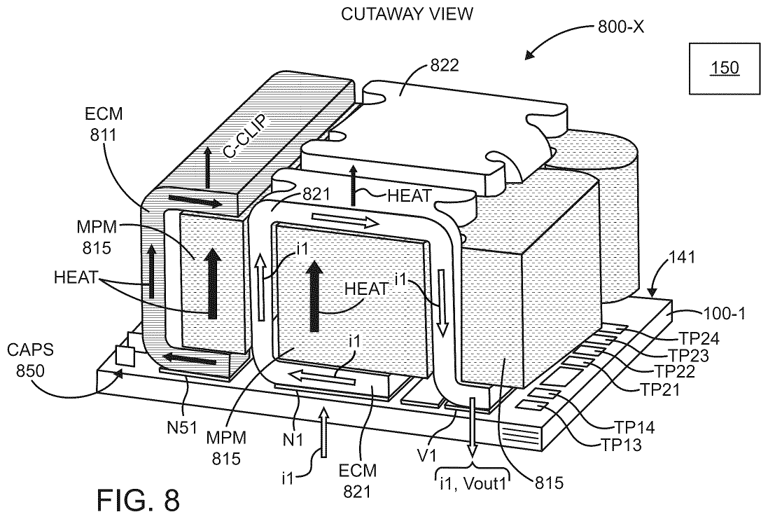

In one example, the driver circuitry and corresponding switches associated with the power converter 200 are disposed in the respective instance of the circuit substrate portion. One or more of the components such as the inductors, capacitors, etc., may be disposed or affixed to one or more respective surface of the final circuit substrate portion to create a respective power converter assembly. See FIG. 8 for an example final assembly including all of the circuit components in the power converter circuit 200.

More specifically, as shown in the power converter circuitry 200, the driver circuitry DC1 of power converter circuit 200 implemented in the respective circuit substrate portion 100-X (where X is any integer value 1, 2, 3, etc.) includes the driver D11, which controls operation of the high side switch circuitry HS1 via a respective control signal that is outputted from the driver D11 to the gate node G of the high side switch circuitry HS1. The driver circuitry DC1 also includes the driver D12, which controls operation of the low side switch circuitry LS1 via a respective control signal that is outputted from the driver D12 to the gate node G of the low side switch circuitry LS1. In one example, the drain node of the high side switch HS1 is connected to receive the input voltage Vin; the source node S of the high side switch HS1 is directly coupled to the drain node D of the low side switch LS1; the source node of the low side switch LS1 is connected to ground. Based on switching of the respective switches HS1 and LS1 on and off over time as controlled by the pulse width modulation controller 211 controlling operation of the respective drivers D11/D12, the respective driver circuitry DC1 and corresponding drivers control flow of respective current from the node N1 through the inductor L1 and corresponding output voltage (VOUT1) outputted from the node V1.

The driver circuitry DC2 of power converter circuit 200 implemented in the respective circuit substrate portion 100-X (where X is any integer value 1, 2, 3, etc.) includes the driver D21, which controls operation of the high side switch circuitry HS2 via a respective control signal that is outputted from the driver D21 to the gate node G of the high side switch circuitry HS2. The driver circuitry DC2 also includes the driver D22, which controls operation of the low side switch circuitry LS2 via a respective control signal that is outputted from the driver D22 to the gate node G of the low side switch circuitry LS2. In one example, the drain node of the high side switch HS2 is connected to receive the input voltage Vin; the source node S of the high side switch HS2 is directly coupled to the drain node D of the low side switch LS2; the source node of the low side switch LS2 is connected to ground. Based on switching of the respective switches HS2 and LS2 on and off over time as controlled by the pulse width modulation controller 212 controlling operation of the drivers D21/D22, the respective driver circuitry DC2 and corresponding drivers control flow of respective current through the inductor L2 and corresponding output voltage (VOUT2) outputted from the node V2.

In one example, the circuit substrate portion 100-X is circuit substrate portion 100-1; circuit substrate portion 100-Y (where Y=X+1) is circuit substrate portion 100-2. In such an instance, the circuit substrate portion 100-Y and corresponding test interface 17X (171) includes, as previously discussed, corresponding test pads: TP11 (for monitoring temperature signal TMON1 associated with the driver circuitry DC1), TP12 (for receiving a respective current monitor signal IMON1 associated with the driver circuitry DC1), TP13 (for inputting a respective pulse width modulation signal PWM1 associated with the driver circuitry DC1), TP14 (for inputting the respective enable signal EN1 associated with the driver circuitry DC1), TP21 (for monitoring temperature signal TMON2 associated with the driver circuitry DC2), TP22 (for receiving a respective current monitor signal IMON2 associated with the driver circuitry DC2), TP23 (for inputting a respective pulse width modulation signal PWM2 associated with the driver circuitry DC2), TP24 (for inputting the respective enable signal EN2 associated with the driver circuitry DC2). As previously discussed, the electrically conductive paths 191 (19X) disposed on the circuit substrate portion 100-Y support connectivity between the respective test pads and the different circuit nodes of the driver circuitry DC1 and driver circuitry DC2.

As further discussed herein, via the application of the test circuit 610 to the test interface 191 and corresponding test pads (TP11, TP12, . . . , TP21, . . . ) disposed on the circuit substrate portion 100-2 (100-Y) for monitoring signals from and supplying signals to the driver circuitries in the power converter circuitry 200, as well as potentially for monitoring different nodes of the circuit substrate portion 100-1, the test circuit 610 trims or calibrates (such as by applying configuration settings to any of) the corresponding driver circuitry in the circuit substrate portion 100-1. During operation, the trim settings are implemented by the driver circuitry to control operation of the respective high side switch and low side switches for each power converter phase in the power converter circuit 200.

Thus, the test pad TP11 disposed on the circuit substrate portion 100-2 can be configured to enable the test circuit 610 to transmit signals to or receive signals from the node 34 of the power converter circuit 200 over a respective electrically conductive path (one of electrically conductive paths 191 such as T11) connecting the test pad TP11 to the node 34 of the circuit substrate portion 100-1; the test pad TP12 disposed on the circuit substrate portion 100-2 can be configured to enable the test circuit 610 to transmit signals to or receive signals from the node 35 of the power converter circuit 200 over a respective electrically conductive path (one of electrically conductive paths 191 such as T12) connecting the test pad TP12 to the node 35 of the circuit substrate portion 100-1; the test pad TP13 disposed on the circuit substrate portion 100-2 can be configured to enable the test circuit 610 to transmit signals to or receive signals from the node 32 of the power converter circuit 200 over a respective electrically conductive path (one of electrically conductive paths 191 such as T13) connecting the test pad TP13 to the node 32 of the circuit substrate portion 100-1; the test pad TP14 disposed on the circuit substrate portion 100-2 can be configured to enable the test circuit 610 to transmit signals to or receive signals from the node 33 of the power converter circuit 200 over a respective electrically conductive path (one of electrically conductive paths 191 such as T14) connecting the test pad TP14 to the node 33 of the circuit substrate portion 100-1; and so on.

As shown in FIG. 2C, the test pad TP21 disposed on the circuit substrate portion 100-2 can be configured to enable the test circuit 610 to transmit signals to or receive signals from the node 29 of the power converter circuit 200 over a respective electrically conductive path (one of electrically conductive paths 191 such as T21) connecting the test pad TP21 to the node 29 of the circuit substrate portion 100-1; the test pad TP22 disposed on the circuit substrate portion 100-2 can be configured to enable the test circuit 610 to transmit signals to or receive signals from the node 30 of the power converter circuit 200 over a respective electrically conductive path (one of electrically conductive paths 191 such as T22) connecting the test pad TP22 to the node 30 of the circuit substrate portion 100-1; the test pad TP23 disposed on the circuit substrate portion 100-2 can be configured to enable the test circuit 610 to transmit signals to or receive signals from the node 27 of the power converter circuit 200 over a respective electrically conductive path (one of electrically conductive paths 191 such as T23) connecting the test pad TP23 to the node 27 of the circuit substrate portion 100-1; the test pad TP24 disposed on the circuit substrate portion 100-2 can be configured to enable the test circuit 610 to transmit signals to or receive signals from the node 28 of the power converter circuit 200 over a respective electrically conductive path (one of electrically conductive paths 191 such as T24) connecting the test pad TP24 to the node 28 of the circuit substrate portion 100-1; and so on.

See additional details of the test pads and corresponding electrically conductive paths in the following drawings.

FIG. 3 is an example 3-D diagram illustrating a sequence of multiple circuit substrate portions (such as including the first layer and a second layer) in a circuit substrate as discussed herein.

In this example, the planar layers (L1, L2, L3, etc.) of the circuit substrate 100 are disposed in the X-Z plane. The layers associated with the circuit substrate 100 and corresponding circuit substrate portions are stacked in the Y-axis. Note that each layer in the circuit substrate 100 may itself include multiple layers.

As previously discussed, the circuit substrate 100 can be configured to include a test interface 171 supporting calibration of any of the one or more components disposed on or in the circuit substrate portion 100-1.

In this example, the test interface 171 spanning the circuit substrate portion 100-1 and the circuit substrate portion 100-2 of the circuit substrate 100 includes a group or sequence of conductive elements such as electrically conductive paths (later referred to as T11, T12, T13, T14, T21, T22, T23, T24, etc.) associated with the test pads (TP11, TP12, TP13, TP14, TP21, TP22, TP23, TP24, etc.) that extend from the test pads disposed on a first surface 141 of the circuit substrate through the one or more layers of the circuit substrate 100 along the y-axis.

As previously discussed, the sequence of conductive elements such as test pads (TP11, TP12, TP13, TP14, TP21, TP22, TP23, TP24, etc.) may be disposed along a boundary (such as including material 161, cut line, etc.) between the first circuit substrate portion 100-1 and the second circuit substrate portion 100-2.

The electrically conductive paths 122 further extend through the material 161 between the circuit substrate portion 100-2 and the circuit substrate portion 100-1. Further, as previously discussed, subsequent implementation of a cut (by the fabricator 150) along the defined boundary (such as sacrificial material 161 including a portion of the electrically conductive paths 122) is operative to sever the multiple electrically conductive paths from extending between the first circuit substrate portion 100-1 and the second circuit substrate portion 100-2. As further discussed herein, as shown in other FIGS., the test pads 192 (such as conductive elements) may be disposed on a surface of the circuit substrate along or adjacent to the defined boundary (such as including temporary substrate material 161) bridging the circuit substrate portion 100-2 and the circuit substrate portion 100-1.

In one example, the circuit substrate 100 further includes the test interface 172 including electrically conductive paths 123 extending between the circuit substrate portion 100-3 and the circuit substrate portion 100-2, where the second electrically conductive paths 123 are operative to support trimming of the second driver circuitry for other circuit complements her circuitry disposed on or in the circuit substrate portion 100-2. In other words, in a similar manner that the test interface 171 is used to calibrate/configure one or more instances of circuitry in the circuit substrate portion 100-1, the fabricator 150 can be configured to use the test interface 172 spanning between the circuit substrate portion 100-3 and the circuit substrate portion 100-2 to calibrate or configure the driver circuitry or other circuitry disposed in the circuit substrate portion 100-2, and so on.

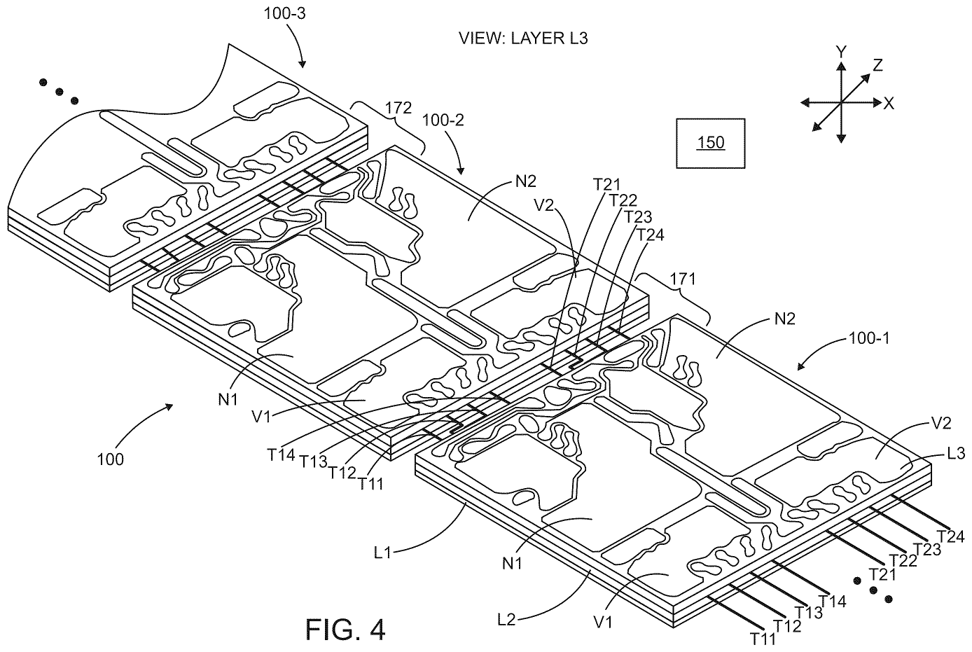

FIG. 4 is an example 3-D diagram illustrating a sequence of multiple circuit substrate portions (such as including the first layer, second layer, and a third layer) in a circuit substrate as discussed herein.

In this example, the fabricator 150 applies the third layer #L3 such as electrically conductive material to produce the nodes or surface pads (node N1, node N2, node V1, node V2, etc.) such as fabricated from metal as shown in FIG. 4.

As previously discussed, the node N1 of the respective circuit substrate portion provides connectivity between the switch circuitry HS1 and the switch circuitry LS1 in the power converter circuit 200 disposed in each of the circuit substrate portions. Node N2 provides connectivity between the switch circuitry HS2 and the switch circuitry LS2 in the power converter circuit 200 disposed in each of the circuit substrate portions.

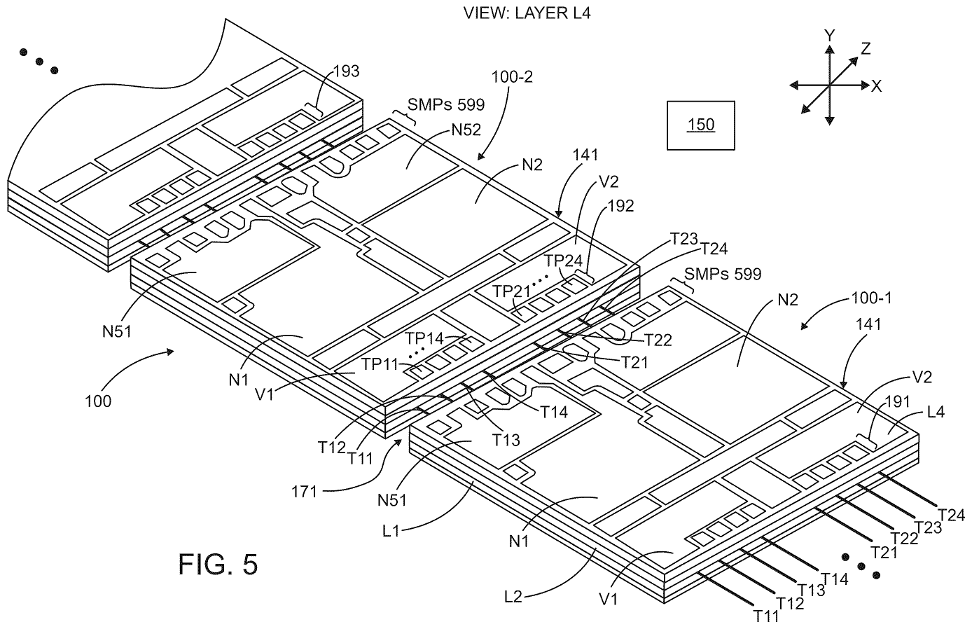

FIG. 5 is an example 3-D diagram illustrating a sequence of multiple circuit substrate portions (such as including the first layer, second layer, the third layer, and a fourth layer) in a circuit substrate as discussed herein.

In this example, the fabricator 150 applies the fourth layer #L4 on top of each third layer #L3 of a respective circuit substrate portion. The fourth layer #L4 includes electrically conductive material (a.k.a., metal or other suitable material) to produce the surface pads or nodes (node N1, node N2, node V1, node V2, heatsink pad N51, heatsink pad N52, etc.) as shown in FIG. 5. The fabricator 150 applies any suitable electrically conductive material (a.k.a., metal, etc.) in or through each of the respective layers to provide appropriate connectivity of nodes from one layer to another.

In one example, FIG. 5 illustrates the final top layer associated with the circuit substrate 100 and corresponding circuit substrate portions. The top surface 141 of the circuit substrate portions of the circuit substrate 100 includes surface mount pads such as associated with nodes N1, N2, V1, V2, etc.

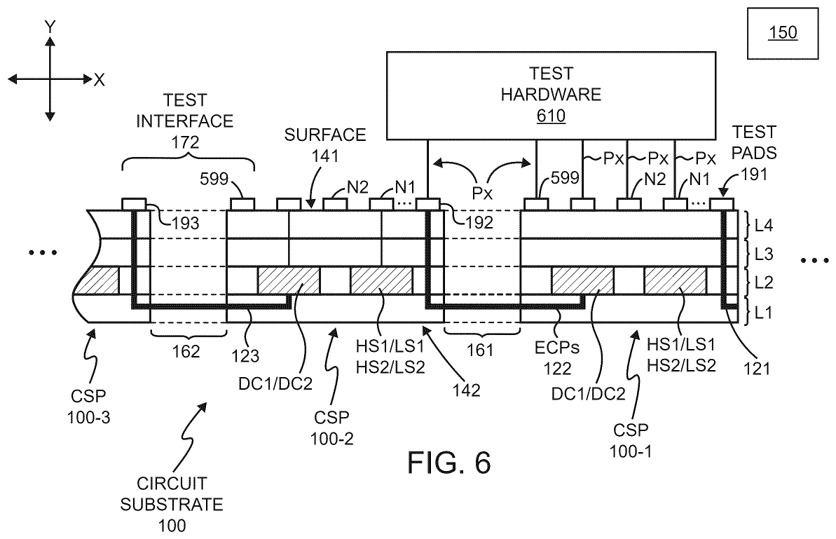

As further shown in FIG. 8, subsequent to configuration is shown in FIG. 6, circuit components such as capacitors, inductors, etc., are affixed to the surface 141 of the respective circuit substrate portion to produce a power converter assembly as captured by the power converter circuit 200 in FIGS. 2A, 2B, 2C, and 2D.

FIG. 6 is an example diagram illustrating application of test hardware in contact with a respective circuit substrate portion to trim or apply configuration settings to circuitry disposed in the respective circuit substrate portion as discussed herein.

In this example, the fabricator 150 applies the test hardware 610 and corresponding one or more probes (a.k.a., test pins) to exposed circuit nodes associated with the circuit substrate portion 100-2 and circuit substrate portion 100-1.

More specifically, the test hardware 610 can be configured to include a respective test pin (or one or more of test pins Px or probes) electrically connected to each of the test pads 192 (TP11, TP12, TP13, TP14, TP21, TP22, TP23, TP24, etc.) associated with the test interface 171. As previously discussed, the respective test pads 192 are electrically connected via corresponding electrically conductive paths 122 (T11, T12, T13, T14, T21, T22, T23, TP4, etc.) to the different nodes of driver circuitry (and any nodes of the power converter circuit) disposed in the circuit substrate portion 100-1.

Thus, via respective test pins Px (a.k.a., probes), the test hardware 610 can be configured to further contact any of the nodes (such as node N1, node N2, node V1, node V2, surface mount pads 599 associated with capacitors in the power converter circuitry 200, etc.) disposed on a surface 141 of the circuit substrate portion 100-1 being tested and configured (such as trimmed, calibrated, etc.).

As previously discussed, calibrating the driver circuitry or other circuit components disposed in or embedded in the circuit substrate portion 100-1 may include, via the test hardware 610,: i) applying one or more signals to respective one or more test pins Px (probes) to respective test pads 192 or surface pads or nodes N1, N2, V1, V2, etc., disposed on a respective surface 141 of the circuit substrate portion 100-1, and ii) receiving one more signals from respective test pads 192 or surface pads or nodes N1, N2, V1, V2, etc., disposed on a respective surface 141 of circuit substrate portion 100-1.

As further shown, and as previously discussed, the first driver circuitry DC1 and DC2 or any other circuitry associated with the power converter circuit 200 may be embedded in the first circuit substrate portion 100-1 between a first surface 141 (such as top surface) of the circuit substrate 100 and a second surface 142 (such as bottom surface) of the circuit substrate 100. The circuit substrate portion 100-1 includes switch circuitry HS1/LS1 controlled by the first driver circuitry DC1 to control respective current through one or more inductors of the power converter circuitry 200 disposed on the respective circuit substrate portion after final assembly.

Accordingly, the circuit substrate 100 as discussed herein can be configured to include: first test pads or surface mount pads (such as N1, N2, V1, V2, etc.) disposed on a first surface 141 of the first circuit substrate portion 100-1; second test pads 192 (such as TP11, TP12, TP13, TP14, etc.) disposed on a surface 141 of the second substrate portion 100-2. Via use of the test hardware 610, a combination of the first test pads (such as surface mount pads N1, N2, V1, V2, etc.) and the second test pads (such as TP11, TP12, TP13, TP14, etc.) support calibration of the first driver circuitry DC1 and the second driver circuitry DC2 disposed or any other circuitry in the circuit substrate portion 100-1 prior to final assembly of affixing inductors, capacitors, etc., to the respective circuit substrate portion to produce the power converter assembly shown in FIG. 8.

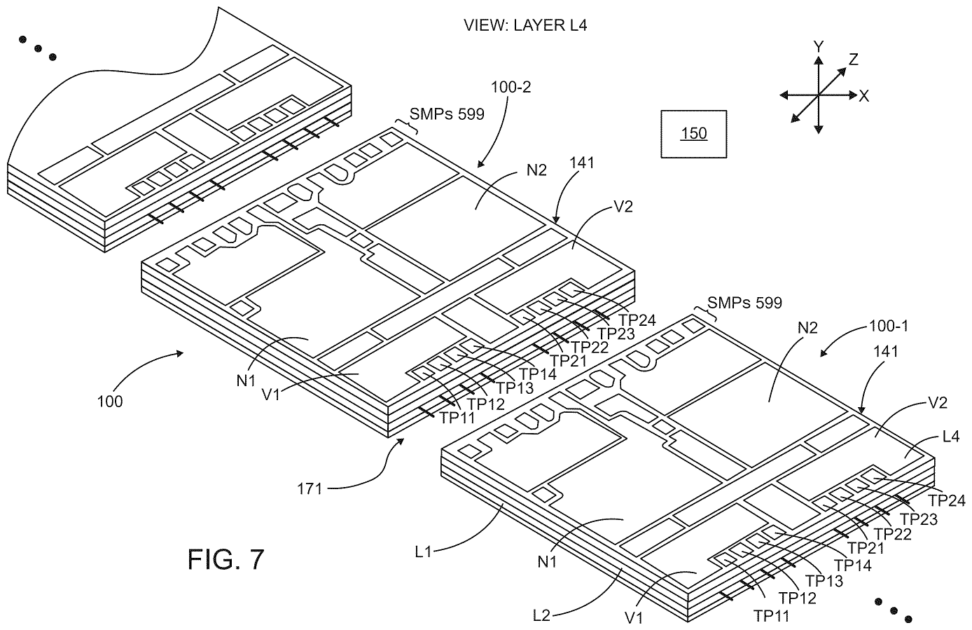

FIG. 7 is an example 3-D diagram illustrating dicing or physical partitioning (separation) of the different instances of circuit substrate portions disposed in the circuit substrate as discussed herein.

In this example, the fabricator 150 implements partitioning of the second circuit substrate portion 100-2 to be electrically isolated from the first circuit substrate portion 100-1.

As previously discussed, the extraneous material 161 may reside between the first circuit substrate portion 100-1 and the second circuit substrate portion 100-2 in the circuit substrate 100. Physical separation or partitioning of the first circuit substrate portions from the second circuit substrate portion may include: i) the fabricator 150 physically removing the extraneous material 161, resulting in severing the at least one electrically conductive path extending between the second circuit substrate portion 100-2 and the first circuit substrate portion 100-1; ii) the fabricator 150 physically removing the extraneous material 162, resulting in severing the at least one electrically conductive path extending between the second circuit substrate portion 100-3 and the first circuit substrate portion 100-2; and so on.

As previously discussed, any of the components associated with the power converter circuitry 200 can be affixed to the respective surface of the circuit substrate portions 100-X to produce the respective power converter assembly is shown in FIG. 8

FIG. 8 is an example 3-D cutaway view diagram illustrating fabrication of a power converter assembly using a pre-calibrated circuit substrate portion as a base as discussed herein.

In this example, the circuit assembly 800-X such as a power converter assembly in accordance with the power converter circuitry 200 includes one or more components coupled to the first circuit substrate portion 100-1.

For example, as shown, the one or more components coupled to the first circuit substrate portion 100-1 may include electrically conductive material 811 extending from a top surface 141 of the first circuit substrate portion 100-1 to a top side of the assembly 800. In one example, the electrically conductive material 811 (such as metal or other suitable material) supports flow of corresponding heat from the first circuit substrate portion 100-1 to a heatsink or entity such as air. The electrically conductive material 811 may be a so-called heatsink clip.

The assembly 800-X includes the magnetically permeable material 815 (such as representing a magnetic core of the inductor L1). The electrically conductive material 821 associated with the inductor L1 such as metal or other suitable entity extends through the magnetically permeable material 815 between the node N1 and the node V1 exposed on the top surface 141 of the circuit substrate portion 100-1. Thus, inductor L1 in this example includes a combination of the magnetically permeable material 815 and the electrically conductive material 821. As previously discussed, the driver circuitry DC1 controls operation of respective switches HS1/LS1 to control a magnitude of the current i1 through the electrically conductive material 821 (inductor L1).

It is noted that the magnetically permeable material 815 can be configured to overhang the test pads 191 disposed on the circuit substrate portion 100-1. Thus, the location of the test pads 191 (used for calibrating the adjacent circuit substrate portion 100-0) does not negatively impact the size of the power converter assembly 800.

Additionally, the one or more capacitors 850 (such as including capacitor C11, C12, C13, C30, C21, C22, C23, etc.) associated with the power converter circuit 200 circuit substrate portion 100-1 can be coupled to corresponding circuit pads (surface mount pads 599) disposed on the surface 141 of the circuit substrate portion 100-1.

The electrically conductive material 822 (such as representing a core of the inductor L2) extends through the magnetically permeable material 815. The electrically conductive material 822 extends through the magnetically permeable material 815 between the surface pad nodes including node N2 and the node V2 exposed on the top surface 141 of the circuit substrate portion 100-1. As previously discussed, the driver circuitry DC2 controls operation of respective switches HS2/LS2 to control a magnitude of the current i2 through the electrically conductive material 822.

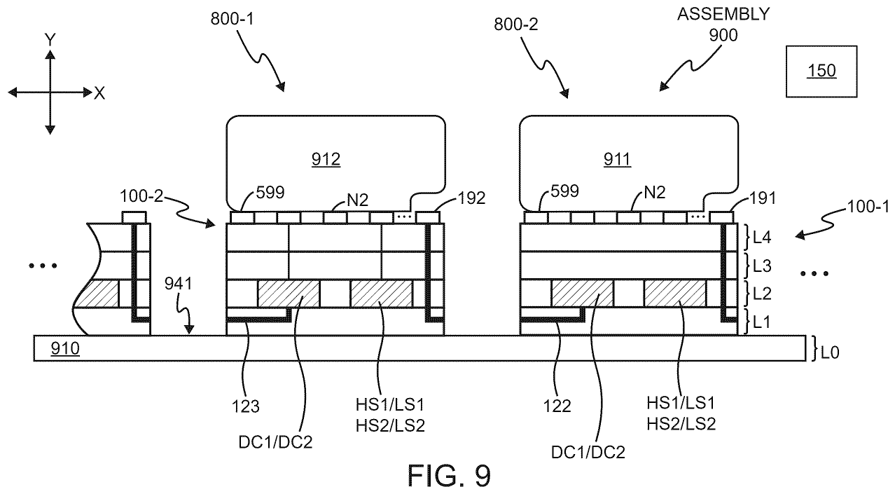

FIG. 9 is an example side view diagram illustrating how implementation of a respective test interface and corresponding test pads do not interfere with implementation of power converter circuitry associated with a respective circuit substrate portion as discussed herein.

In this example, the assembly 900 includes host substrate 910 as well as multiple instances of the power converter assembly 800-X as previously discussed in FIG. 8. The multiple instances of the power converter assembly 800 may include power converter assembly 800-1, the power converter assembly 800-2, etc., affixed to the substrate 910.

The power converter assembly 800-1 includes the circuit substrate portion 100-1 as a base as well as corresponding circuitry 911 such as capacitors, inductors, magnetic permeable material, electrically conductive material, etc., as previously discussed in FIG. 8 affixed to the surface 141 of the corresponding instance of the circuit substrate portion disposed in the assembly 800-X.

In a similar manner, the power converter assembly 800-2 includes the circuit substrate portion 100-2 as a base as well as corresponding circuitry 912 such as capacitors, inductors, magnetic permeable material, electrically conductive material, etc., as previously discussed in FIG. 8.

As further shown in FIG. 9, the host substrate 910 such as a printed circuit board or other suitable entity is disposed at layer #L0. The host substrate 910 itself may be fabricated from multiple layers to support conveyance of signals, voltages, current, etc., over different electrically conductive paths therein.

The first instance of the power converter assembly 800-1 is coupled to a top surface 941 of the host substrate 910. In a similar manner, the second instance of the power converter assembly 800-2 is coupled to the top surface 941 of the host substrate 910. If desired, the power converters in each of the power converter assemblies 800-1 and 800-2 can operate in parallel to convert an input voltage (such as a DC voltage) into a respective output voltage (such as a DC voltage).

In one example, the substrate 910 supplies the input voltage Vin and corresponding ground to each of the different instances of the assembly 800-1, 800-2, etc. The power converter assemblies 800 convert the received input voltage into a respective one or more output voltages supplied by the power converter assemblies to the host substrate 910. The host substrate 910 can be configured to supply the generated one or more output voltages to a respective load.

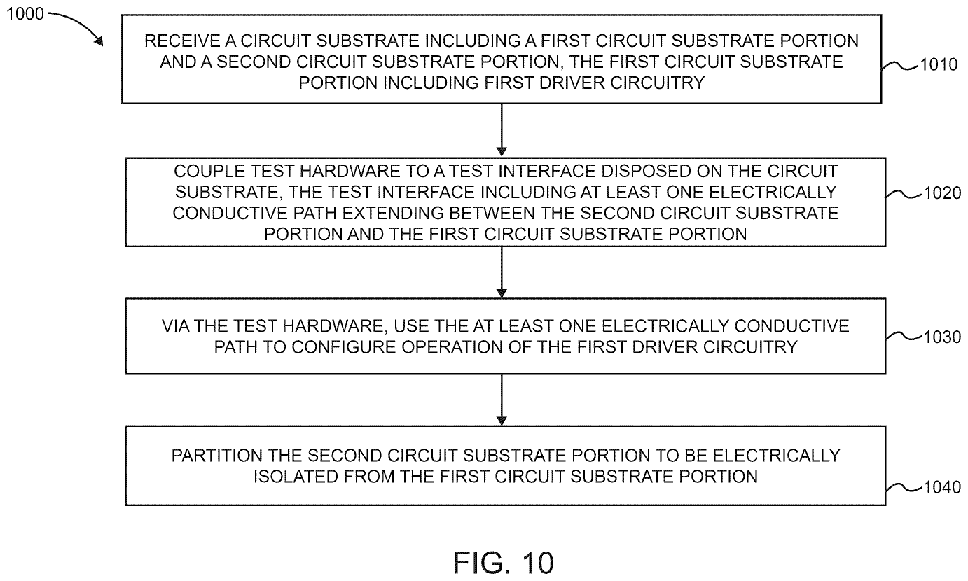

FIG. 10 is an example diagram illustrating fabrication of a respective circuit substrate to support configuration of circuitry associated with power converters as discussed herein.

In one example, in processing operation 1010 associated with the flowchart 1000, a fabricator resource 150 or other suitable entity receives a circuit substrate 100 including a first circuit substrate portion and a second circuit substrate portion. As previously discussed, the circuit substrate 100 can be configured to include any number of circuit substrate portions. The first circuit substrate portion may include respective first driver circuitry to control operation of respective switches in the first circuit substrate portion.

In processing operation 1020, the fabricator resource 150 or other suitable entity couples test hardware 610 to a test interface disposed on the circuit substrate 100. As previously discussed, the test interface can be configured to span across multiple adjacent circuit substrate portions of the circuit substrate 100. For example, the test interface 171 includes at least one electrically conductive path extending between the second circuit substrate portion 100-2 and the first circuit substrate portion 100-1. Note that coupling the test hardware 610 to the test interface 171 disposed on the circuit substrate 100 may include: i) contacting a first one or more test pins Px of the test hardware 610 to one or more first conductive elements (test pads) disposed on a surface of the second circuit substrate portion 100-2, and ii) contacting a second one or more test pins of the test hardware 610 to the one or more second conductive elements (surface mount pads) disposed on the surface of the first circuit substrate portion 100-1.

In processing operation 1030, the fabricator 150 or other suitable entity operates the test hardware 610 to use the multiple electrically conductive paths 122 to configure, via configuration settings applied to each respective circuit substrate portion, operation of the first circuitry disposed in the circuit substrate portion 100-1.

In processing operation 1040, the fabricator 150 or other suitable entity physically partitions the second circuit substrate portion 100-2 to be electrically isolated from the first circuit substrate portion 100-1. Note that the partitioning may include the fabricator 150 removing of any extraneous material 161 between the first circuit substrate portion 100-1 and the second circuit substrate portion 100-2, resulting in physical severing the at least one electrically conductive path and any portion of the circuit substrate 100 extending between the second circuit substrate portion 100-2 and the first circuit substrate portion 100-1.

Note again that the fabricator 150 can be configured to implement the physical separation of the different circuit substrate portions at any time such as: i) before affixing additional circuit components to a respective surface of each of the first circuit substrate portion and the second circuit substrate portion prior, or ii) after affixing additional circuit components to a respective surface of each of the first circuit substrate portion and the second circuit substrate portion.

Note again that techniques herein are well suited for use in power converter assemblies. However, it should be noted that examples herein are not limited to use in such applications and that the techniques discussed herein are well suited for other applications as well.

Based on the description set forth herein, numerous specific details have been set forth to provide a thorough understanding of claimed subject matter. However, it will be understood by those skilled in the art that claimed subject matter may be practiced without these specific details. In other instances, methods, apparatuses, systems, etc., that would be known by one of ordinary skill have not been described in detail so as not to obscure claimed subject matter. Some regions of the detailed description have been presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm as described herein, and generally, is considered to be a self-consistent sequence of operations or similar processing leading to a desired result. In this context, operations or processing involve physical manipulation of physical quantities. Typically, although not necessarily, such quantities may take the form of electrical or magnetic signals capable of being stored, transferred, combined, compared or otherwise manipulated. It has been convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, as apparent from the following discussion, it is appreciated that throughout this specification discussions utilizing terms such as “processing,” “computing,” “calculating,” “determining” or the like refer to actions or processes of a computing platform, such as a computer or a similar electronic computing device, that manipulates or transforms data represented as physical electronic or magnetic quantities within memories, registers, or other information storage devices, transmission devices, or display devices of the computing platform.

While this invention has been particularly shown and described with references to preferred examples thereof, it will be understood by those skilled in the art that various changes in form and details may be made therein without departing from the spirit and scope of the present application as defined by the appended claims. Such variations are intended to be covered by the scope of this present application. As such, the foregoing description of examples of the present application is not intended to be limiting. Rather, any limitations to the invention are presented in the following claims.

1. An assembly comprising:
a circuit substrate including a first circuit substrate portion and a second circuit substrate portion, the first circuit substrate portion including first driver circuitry; and
a test interface including at least one electrically conductive path extending between the second circuit substrate portion and the first circuit substrate portion, the at least one electrically conductive path operative to support trimming of the first driver circuitry.

2. The assembly as in claim 1, wherein the first circuit substrate portion includes first switch circuitry controlled by the first driver circuitry.

3. The assembly as in claim 2, wherein the first switch circuitry includes a first switch and a second switch controlled by the first driver circuitry; and
wherein the first circuit substrate portion includes a first conductive element disposed on a first surface of the first circuit substrate portion, the first conductive element electrically connected to both a source node of the first switch and a drain node of the second switch.

4. The assembly as in claim 2, wherein the second circuit substrate portion includes second driver circuitry operative to control second switch circuitry disposed in the second circuit substrate portion, the second switch circuitry including third switch and a fourth switch controlled by the second driver circuitry.

5. The assembly as in claim 1, wherein the first circuit substrate portion is disposed adjacent to and contiguous with respect to the second circuit substrate portion.

6. The assembly as in claim 1, wherein the test interface further includes a group of conductive elements disposed on a first surface of the circuit substrate, the conductive elements including a first conductive element and a second conductive element;
wherein the at least one electrically conductive path includes a first electrically conductive path and a second electric path; and
wherein the first electrically conductive path extends between the first conductive element and a first node of the first driver circuitry; and
wherein the second electrically conductive path extends between the second conductive element and a second node of the first driver circuitry.

7. The assembly as in claim 6, wherein at least a portion of the first electrically conductive path is disposed internal to the circuit substrate between the first surface of the circuit substrate and a second surface of the circuit substrate; and
wherein at least a portion of the second electrically conductive path is disposed internal to the circuit substrate between the first surface of the circuit substrate and a second surface of the circuit substrate.

8. The assembly as in claim 1, wherein the test interface further includes a sequence of conductive elements disposed on a first surface of the circuit substrate, the sequence of conductive elements including a first conductive element and a second conductive element, the sequence of conductive elements disposed along a boundary between the first circuit substrate portion and the second circuit substrate portion.

9. The assembly as in claim 1, wherein the at least one electrically conductive path includes multiple electrically conductive paths;
wherein the circuit substrate includes a defined boundary between the first circuit substrate portion and the second circuit substrate portion, the multiple electrically conductive paths passing through the defined boundary; and
wherein subsequent implementation of a cut along the defined boundary is operative to sever the multiple electrically conductive paths from extending between the first circuit substrate portion and the second circuit substrate portion.

10. The assembly as in claim 9, wherein the test interface includes electrically conductive elements disposed on a surface of the circuit substrate along the defined boundary.

11. The assembly as in claim 1, wherein the at least one electrically conductive path includes first electrically conductive paths extending between the second circuit substrate portion and the first circuit substrate portion;
wherein the circuit substrate includes a third circuit substrate portion disposed adjacent to the second circuit substrate portion; and
wherein the second substrate portion includes second driver circuitry.

12. The assembly as in claim 11, wherein the test interface includes second electrically conductive paths extending between the third circuit substrate portion and the second circuit substrate portion, the second electrically conductive paths operative to support trimming of the second driver circuitry.

13. The assembly as in claim 1, wherein the first driver circuitry is embedded in the first circuit substrate portion between a first surface of the circuit substrate and a second surface of the circuit substrate.

14. The assembly as in claim 13, wherein the first circuit substrate portion includes switch circuitry controlled by the first driver circuitry, the switch circuitry including a first switch electrically coupled to a second switch.

15. The assembly as in claim 1 further comprising:
first test pads disposed on a first surface of the first circuit substrate portion;
second test pads disposed on a second surface of the second substrate portion; and
the first test pads and the second test pads operative to support calibration of the first driver circuitry.

16. The assembly as in claim 15, wherein the first test pads electrically connected to a first circuit in the first circuit substrate portion, the first circuit given by the first driver circuitry; and
wherein the second test pads are electrically connected to the first driver circuitry and the at least one electrically conductive path.

17. A method comprising:
receiving a circuit substrate including a first circuit substrate portion and a second circuit substrate portion, the first circuit substrate portion including first driver circuitry;
coupling test hardware to a test interface disposed on the circuit substrate, the test interface including at least one electrically conductive path extending between the second circuit substrate portion and the first circuit substrate portion;
via the test hardware, using the at least one electrically conductive path to configure operation of the first driver circuitry; and
partitioning the second circuit substrate portion to be electrically isolated from the first circuit substrate portion.

18. The method as in claim 17, wherein partitioning the second circuit substrate portion to be electrically isolated from the first circuit substrate portion includes physically severing the at least one electrically conductive path extending between the second circuit substrate portion in the first circuit substrate portion.

19. The method as in claim 17, wherein the first circuit substrate portion is disposed adjacent to and contiguous with respect to the second circuit substrate portion prior to the partitioning.

20. The method as in claim 18, wherein the test interface further includes a group of conductive elements disposed on a first surface of the circuit substrate, the conductive elements including a first conductive element and a second conductive element;
wherein the at least one electrically conductive path includes a first electrically conductive path and a second electric path; and
wherein the first electrically conductive path extends between the first conductive element and a first node of the first driver circuitry; and
wherein the second electrically conductive path extends between the second conductive element and a second node of the first driver circuitry;
wherein coupling the test hardware to a test interface disposed on the circuit substrate includes: i) contacting a first test pin of the test hardware to the first conductive element, and ii) contacting a second test pin of the test hardware to the second conductive element; and
wherein using the at least one electrically conductive path to configure operation of the first driver circuitry includes: i) receiving a first signal communicated from the first node of the first driver circuitry over a combination of the first electrically conductive path and the first conductive element, and ii) transmitting a second signal through the second test pin of the test hardware over the second electrically conductive path to the second node of the first driver circuitry.
